(19) United States
(12) Patent Application Publication
(10) Pub. No.: US 2026/0011564 A1
(43) Pub. Date: Jan. 8, 2026

(54) METHOD FOR FABRICATION OF FINE-FEATURED ETCH MASK USING DIRECT ATOMIC LAYER PROCESSING

(71) Applicants: ATLANT 3D ,ApS, Taastrup (DK); The IP Law Firm of Guy Levi, LLC, Wyckoff, NJ (US)

(72) Inventors: Karolis Parfeniukas, Kobenhaven (DK); Ivan Kundrata, Drahvoce (SK)

(21) Appl. No.: 19/123,022

(22) PCT Filed: Jan. 12, 2025
(86) PCT No.: PCT/US25/11322

§ 371 Date: Apr. 21, 2025

Related U.S. Application Data
(60) Provisional application No. 63/620,403, filed on Jan. 12, 2024.

(51) Int. Cl. H01L 21/308; C23C 16/455; C23C 16/56; G03F 7/16; G03F 7/20

(52) U.S. Cl. CPC H01L 21/3086; C23C 16/45527; C23C 16/56; G03F 7/16; G03F 7/2004

(57) ABSTRACT

The disclosure relates to systems and methods for forming etch masks using direct atomic layer processing. Specifically, the disclosure relates to methods of forming etch masks having fine features at the substrate level, using microreactor direct atomic layer processing (μDALP).

### BACKGROUND

The disclosure is directed to systems and methods for forming masks using direct atomic layer processing. Specifically, the disclosure is directed to methods of forming etch masks having fine features at the substrate level, using direct atomic layer processing (DALP).

In the field of semiconductor technology and materials science, precise control over material removal at the atomic level has become imperative due to the ever-existing need for miniaturization.

In the context of semiconductor processing, the etching mask, is used to transfer a predetermined pattern onto a substrate, typically a silicon wafer in semiconductor manufacturing. The purpose of a mask is to define the desired pattern, which represents the features to be created on the substrate, such as transistors, interconnects, or other microstructures. The mask essentially acts as a stencil for the patterning process, allowing specific areas of the substrate to be exposed to light or other forms of energy (e.g., plasma) or wet chemical etch while protecting the rest.

Although etching masks with fine features do exist, their resolution is fundamentally constrained by the Rayleigh criterion, which depends on the wavelength of light, numerical aperture (NA), and process factors. (see e.g., FIG. 1). For example, in photolithography the additive process of defining the etching mask itself prior to etching. The formation of etching masks with fine features in semiconductor manufacturing presents a set of intricate challenges, with the fundamental issue lying in pushing the limits of optical lithography. Achieving high pattern fidelity, where the mask accurately represents the intended design, becomes increasingly difficult the finer the features, with imperfections and distortion leading to errors in the final pattern. Crucial for aligning multiple mask layers is precise overlay accuracy, which is challenging and is susceptible to misalignment and defects. Additionally, material compatibility, mask durability, inspection methods, uniformity, and process control are all exacerbating factors when dealing with fine features. Resolution enhancement techniques, environmental factors, and the costs associated with developing advanced (optionally multilayer) masks further complicate the process.

The proposed methods and system aim to address these challenges.

### SUMMARY

Disclosed, in various exemplary implementations, are systems and methods for forming etch masks using direct atomic layer processing. Specifically, disclosed herein, are methods of forming etch masks having fine features at the substrate level, using direct atomic layer processing (DALP).

In an exemplary implementation provided herein is a method of forming an etching mask, or a portion thereof for lithography in a semiconductor production process, the etching mask having its smallest feature at a substrate plane, implemented in a microreactor direct atomic layer deposition (μDALP) system, the method comprising: using the μDALP system, depositing and/or removing a first strip; and using the μDALP system, depositing and/or removing a second strip, wherein: the first and second strips are configured to form a crossing pattern with a predetermined overlap region; and the crossing pattern adapted, sized, and configured to form two acute angles with the smallest feature defined at the acute angle formed by the first strip and the second strip forming at least the portion of the etching mask.

These and other features of the methods of forming etch masks having fine features at the substrate level, using direct atomic layer processing (DALP), will become apparent from the following detailed description when read in conjunction with the figures and examples, which are exemplary, not limiting.

### BRIEF DESCRIPTION OF THE FIGURES

For a better understanding of the methods of forming etch masks having fine features at the substrate level, using direct atomic layer processing (DALP), with regard to the exemplary implementations thereof, reference is made to the accompanying examples and figures, in which:

FIG. 1, is a flow chart of a typical process for the formation of an etch mask on a wafer substrate;

FIG. 2A, illustrates a 2D ellipsometry image of titanium oxide stripes on silicon oxide/Silicon wafer (SiO₂/Si), with FIG. 2B depicting a 3D representation of a surface profile measurement using ellipsometry;

FIG. 3, depicts a close-up image of a 3D representation of a surface profile measurement using ellipsometry of platinum stripes on silicon oxide coated Silicon wafer;

FIG. 4A, is a schematic illustrating an exemplary implementation of the method of forming the etching mask, with FIG. 4B, illustrating another exemplary implementation; and

FIG. 5, illustrates the use of the etching mask as a 3D mask for shaping wafer surface.

### DETAILED DESCRIPTION

Provided herein are exemplary implementations of devices, systems and methods of forming etch masks having fine features at the substrate level, using direct atomic layer processing (DALP).

Direct Atomic Layer Processing (DALP) refers in an exemplary implementation to a precise thin film deposition or removal (e.g., Atomic Layer Etching) technique enabling the growth or removal of uniform and conformal films at the atomic scale.

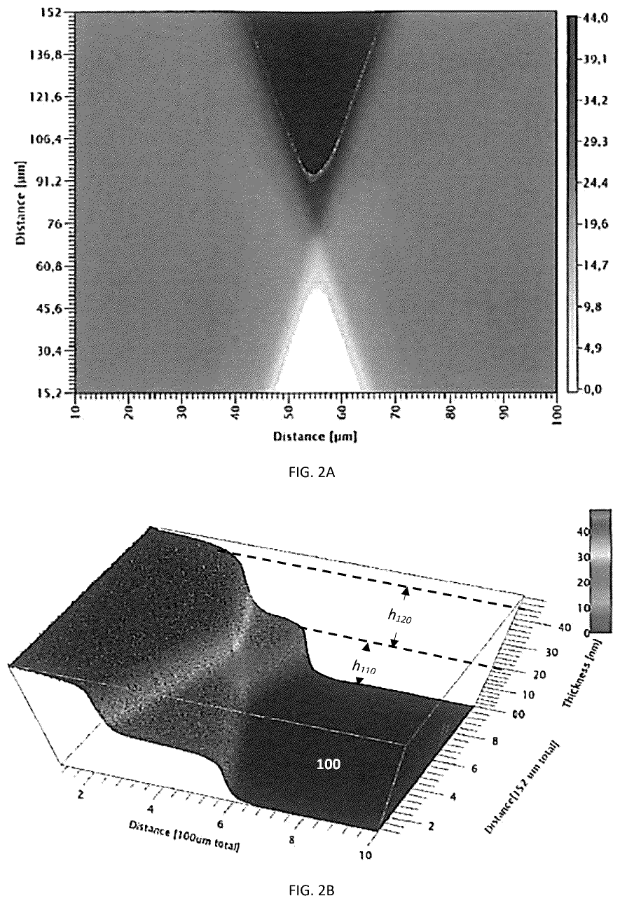

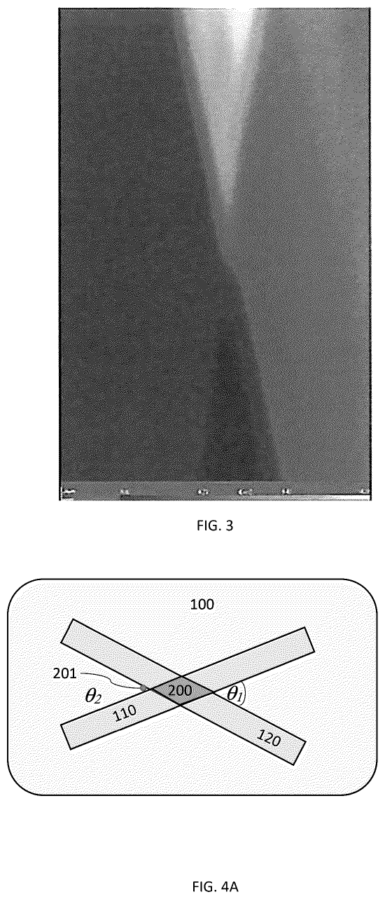

In the case of film deposition, using DALP, film growth is done in a controlled, layer-by-layer fashion beginning with modifying the substrate surface that is chemically prepared, typically cleaned to remove any contaminants or oxides. The deposition starts with an initial reactant, called the precursor, being introduced into a (micro) reaction chamber (e.g., for micro DALP, or μDALP). The precursor is selected based on the desired film composition, properties, and the expected etching methodology used. The precursor can be a vapor or gas-phase fluid that can react with, or preferentially adhere to the modified substrate surface. The precursors' flows are precisely timed and controlled to ensure interaction with the modified substrate surface (e.g., silicon oxide wafer, see e.g., FIG. 2A-3) for a defined period. During this exposure, a self-limiting reaction occurs configured to terminate once a full monolayer is formed at the surface, resulting in the formation of a monolayer or sub-monolayer of the desired material. Excess precursor, unreacted byproducts, and any adsorbed impurities are then purged from the chamber using an inert gas such as, for example, nitrogen or argon. The cycle of precursor deposition, purge, reactant deposition and purge is then repeated, alternating between initial precursor exposure and final purge steps, thereby gradually building up the film layer by layer. The number of cycles is carefully controlled to achieve the desired film thickness, which can range from a few nanometers to several micrometers. The layer-by-layer growth using (microreactor) DALP ensures uniformity, even on complex 3D structures such as trenches, pores, or high aspect ratio (>>1) features. The resulting film strips can be configured to exhibit uniform thickness and width with excellent control over composition and properties. The microreactor is created by confining the whole operation within a discrete volume, where the nozzle, in fluid communication with the various precursors and reactants is positioned and is substantially sealed above the operating area where deposition, and/or etching takes place.

In an exemplary implementation, the precursor, or reactant used in the (microreactor) DALP film forming methods disclosed can be, for example, at least one of: Trimethylaluminum (TMA), Tetrakis(dimethylamino)titanium (TDMAT), Bis(cyclopentadienyl)zirconium (IV) dichloride (Cp2ZrCl2), Tetrakis (ethylmethylamino) hafnium (TEMAH), and Bis(ethylcyclopentadienyl) ruthenium(II) (Ru(EtCp)2), Titanium tetrachloride (TiCl4), Tungsten hexafluoride (WF6), Hafnium tetrachloride (HfCl4), Ruthenium trichloride (RuCl3), and Molybdenum hexacarbonyl (Mo(CO)6), Diethyl zinc (DEZ), Dimethylamino magnesium (DMAMg), Bis(cyclopentadienyl) iron(II) (Cp2Fe), Triisobutylaluminum (TIBA), Tetrakis(trimethylsilyl)hafnium (TTHf), Aluminum isopropoxide (Al(O-iPr)3), Titanium isopropoxide (Ti(O-iPr)4), Zirconium n-propoxide (Zr(O-nPr)4), Hafnium ethoxide (Hf(OEt)4), Tantalum ethoxide (Ta(OEt)5), Bis(t-butylamino)silane (BTBAS), Bis(t-butylamino)zinc (BTBAS2), Bis(t-butylamino)titanium (BTBAT), Bis(t-butylamino)zirconium (BTBZ), Bis(t-butylamino)hafnium (BTBAH), Dimethylcyclopentadienyl platinum (MeCpPtMe3), Bis(methylcyclopentadienyl)nickel (Ni(MeCp)2), Cyclopentadienyltungsten tricarbonyl (CpW(CO)3), Dimethylcyclopentadienyl manganese tricarbonyl (MeCpMn(CO)3), and Iron pentacarbonyl (Fe(CO)5).

For example, in an exemplary implementation, the precursor is Trimethylaluminum (TMA), and the reactant is Ozone, forming a layer of aluminum oxide (Al₂O₃), releasing methane (CH₄) on purge, allowing for example the formation of thin films having varying band gap for various electronic applications ranging from gate dielectric in metal-oxide-semiconductor (MOS) transistors to trapping or blocking insulator in charge trapping nonvolatile memory cells. In another exemplary implementation, the precursor is Tetrakis (dimethylamino) titanium (TDMAT) and the reactant can be Oxygen plasma (or again Ozone (O₃), hydrogen peroxide (H₂O₂), or water vapor), forming Titanium Oxide (TiO₂) films. Other reactants that can be used are Hydrazine (N₂H₄), Ammonia (NH₄), or Nitrogen Fluoride (NF₄).

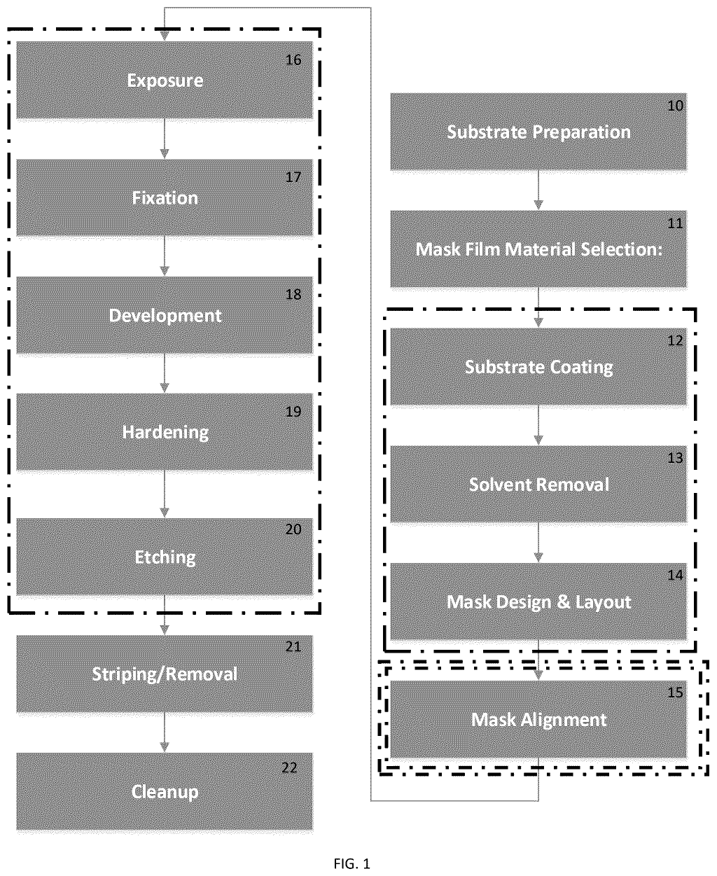

Surface treatment of the substrate (see e.g., 10—FIG. 1) used in the methods described herein can be at least one of: solvent (e.g., acetone, isopropyl alcohol (IPA), or ultrasonic cleaning to remove organic contaminants and particles) or acid (e.g., sulfuric acid (H₂SO₄) or hydrochloric acid (HCl)), cleaning; plasma (e.g., using reactive gases like oxygen (O2), hydrogen (H2), or fluorine-based gases (CF₄, SF₆), is done to remove native oxide layers or to pattern the substrate surface, for example, forming alignment fiducials), and/or wet (e.g., to remove unwanted layers or roughen the surface for improved film adhesion for example) etching; and surface functionalization (e.g., silane coupling agents, such as APTES (aminopropyltriethoxysilane) or HMDS (hexamethyldisilazane), by introducing specific chemical groups that enhance film bonding or modify surface energy).

In an exemplary implementation, alignment markers, or fiducials formed using the methods and systems disclosed, are reference points or patterns intentionally placed on semiconductor wafers during fabrication, configured to enable precise alignment of photomask layers in the lithography processes. These markers are beneficial for ensuring that successive layers of the integrated circuit align accurately, minimizing defects and maintaining the integrity of the device's design. Fiducials are created in certain exemplary implementations, using etched or deposited materials that contrast with the wafer surface, allowing optical systems to detect and align them with high precision, advantageous in advanced semiconductor manufacturing, where feature sizes are on the nanometer scale and even minor misalignments can compromise device performance.

Conversely, and in another exemplary implementation, the etching mask is formed by removing material using (micro) direct atomic layer processing (DALP). Atomic Layer Etching (ALEt) (interchangeable with material removal using DALP) refers to a precise a highly controlled layer-by-layer removal of material. In a typical DALP for material removal, a substrate (e.g., a wafer, an integrated circuit) serving as the foundation, the surface atomic layer undergoes modification through a self-limiting adsorption reaction, involving either molecular entities or low-energy radicals. Subsequently, this modified surface layer is subjected to interaction with an appropriate ligand or reactant. The function of the ligand (interchangeable with the term “reactant”) is its ability to form bonds with the altered surface atomic layer. This interaction facilitates the etching of the modified surface layer either through the application of elevated temperatures or, additionally or alternatively, by exploiting the condition where the reaction layer of the modified surface with the ligand and/or its byproducts exhibits a sufficiently low vapor pressure, enabling straightforward extraction from the vicinity of the surface from exhaust channels. The removal process is configured to preclude the decomposition of these substantial molecules, thereby averting any potential for their re-deposition onto the substrate.

Another layer-removal method using (microreactor) DALP used in the methods disclosed, can be where the substrate's surface layer is modified using either neutrals (i.e., elements without an electric charge), radicals or other reactive molecules. Initially, the surface layer can be bombarded by energetic ions or neutrals to break the bonds of the surface layer of atoms, resulting in the release of the volatile byproducts, which is subsequently purged from the microreactor, enabling formation of an anisotropic atomic layer removal of material. In an exemplary implementation, the modified surface layer released during the bombardment process is configured to produce a stable volatile by-product, enabling efficient purging out of the microreactor. For example, an atomic layer of SiO2 is removed using a combination of C₄F₈ plasma to create a surface fluorocarbon (FC) layer followed by an ion bombardment with low-energy Ar⁺ ions to remove the surface FC layer. Likewise, an atomic layer of Si, GaAs5, or Ge is removed in another example using a combination of Cl₂ adsorption and neutral Ne beam.

Another method of layer removal can be used in combination with the above mentioned methods. Traditional dry including but not limited to reactive ion etching (RIE), deep reactive ion etching (DRIE), as well as wet etching methods can be used.

In the ALEt disclosed herein, various surface modifiers can be employed to enable precise and selective material removal at the atomic scale. These can be, for example, plasma activation, hydrogen (H₂) activation, chlorine (Cl₂) activation, fluorine (F₂) activation, and oxygen (O₂) activation, which modify the surface chemistry to facilitate subsequent etching steps. Organic ligands and silane-based chemistries can also be used to create tailored surface terminations for selectivity. In exemplary implementations involving metal-containing materials, metal chlorides may serve as surface modifiers. Selection of the first surface modifier depends in another exemplary implementation, on the specific materials and desired etching selectivity.

Likewise, the ligands and precursors used can be, for example, at least one of: hydrogen fluoride (HF), tetrafluoromethane (CF₄), sulfur hexafluoride (SF₆), nitrogen trifluoride (NF₃), and hexafluoropropylene (C₃F₆). These ligands can react with the surface to introduce fluorine groups, rendering Fluorine-modified surface selectively etchable. The choice of ligand or precursor is contingent upon the specific substrate materials being processed and the desired level of selectivity. In another exemplary implementation, the surface is modified using Chlorine and the ligand is at least one of: hydrogen chloride (HCl), and dichlorosilane (SiH₂Cl₂).

In another exemplary implementation, the inert gas used for purging, whether in deposition or removal, can be at least one of: Nitrogen, Argon, Helium, and Neon. It is noted that the choice of inert gas depends on factors such as process requirements, film properties, equipment capabilities, and cost considerations.

It should be noted that the exact reaction mechanism in both DALP deposition and material removal may involve simultaneous deposition and etching reactions. Competition between the growth rate and the etching rate is expected. The exact etching mechanism is dependent on the precise conditions, including temperature, pressure, and gas flow rates, all which are carefully controlled to drive the desired chemical reactions and etch rate.

In an exemplary implementation, the purpose of the etching mask formed using the methods disclosed herein is to define the desired pattern, which represents the features to be created on the substrate, such as transistors, interconnects, interposers, or other microstructures (e.g., through via locations), allowing specific areas of the substrate to be exposed to light or other forms of energy while protecting the rest. The process can therefore serve for performing quality assurance (QA) and quality control (QC) procedures for the etching process. For example, by forming strips having thickness configured to be etched completely during the etching process, it is possible to have a visual confirmation of how effective was the etching process.

In semiconductor manufacturing, feature sizes are typically measured in nanometers (nm), and a “small feature” is usually associated with more advanced and densely packed components, allowing for higher performance and miniaturization. Accordingly, reducing feature size on etching masks allows for the creation of more complex and precise patterns.

In an exemplary implementation, the first surface modifier, or reactant used in the (microreactor) DALP methods disclosed can be, for example, at least one of: Trimethylaluminum (TMA), Tetrakis(dimethylamino)titanium (TDMAT), Bis(cyclopentadienyl)zirconium(IV) dichloride (Cp₂ZrCl₂), Tetrakis(ethylmethylamino)hafnium (TEMAH), and Bis(ethylcyclopentadienyl)ruthenium(II) (Ru(EtCp)₂), Titanium tetrachloride (TiCl₄), Tungsten hexafluoride (WF₆), Hafnium tetrachloride (HfCl₄), Ruthenium trichloride (RuCl₃), and Molybdenum hexacarbonyl (Mo(CO)₆), Diethyl zinc (DEZ), Dimethylamino magnesium (DMAMg), Bis(cyclopentadienyl)iron(II) (Cp₂Fe), Triisobutylaluminum (TIBA), Tetrakis(trimethylsilyl)hafnium (TTHf), Aluminum isopropoxide (Al(O-iPr)₃), Titanium isopropoxide (Ti(O-iPr)₄), Zirconium n-propoxide (Zr(O-nPr)₄), Hafnium ethoxide (Hf(OEt)₄), Tantalum ethoxide (Ta(OEt)₅), Bis(t-butylamino)silane (BTBAS), Bis(t-butylamino)zinc (BTBAS₂), Bis(t-butylamino)titanium (BTBAT), Bis(t-butylamino)zirconium (BTBZ), Bis(t-butylamino)hafnium (BTBAH), Dimethylcyclopentadienyl platinum (MeCpPtMe₃), Bis(methylcyclopentadienyl)nickel (Ni(MeCp)₂), Cyclopentadienyltungsten tricarbonyl (CpW(CO)₃), Dimethylcyclopentadienyl manganese tricarbonyl (MeCpMn(CO)₃), Iron pentacarbonyl (Fe(CO)₅), Al(CH₃)₃, AlCl(CH₃)₂, Sn(acac)₂, BCl₃, Hhfac, HCOOH, PMe₃, dHF, Ga(CH₃)₃, SiCl₄, TiCl₄ and HCl.

In another exemplary implementation, the inert gas can be at least one of: Nitrogen, Argon, Helium, and Neon. It is noted that the choice of inert gas depends on factors such as process requirements, film properties, equipment capabilities, and cost considerations. Additionally, specific applications or variations within (micro) DALP material removal techniques may call for the use of other inert gases or gas mixtures.

In addition, another exemplary implementation, the reactant, co-reactant or co-reagent in gas or plasma phase can be one or a mixture of: O₃ HF, CHF₃, CF_{4·}, H₂, NF₃, XeF₂, BCl₃/Cl₂, C₄H₃F₇O, C₃H₃F₃, HBr, O₂, O₃, CF₄/O₂ F₂/He, C₄F₈, CH₃F, Al(CH₃)₃, C₄F₈ plasma, WF₆, BCl₃, SF₄, SO₂Cl₂, and acetylacetone (Hacac). It is noted that the choice of reactant depends on factors such as process requirements, film properties, equipment capabilities, and cost considerations. Additionally, specific applications or variations within (microreactor) DALP material removal techniques may call for the use of other reagents or reagent gas mixtures.

Surface treatment of the substrate used in the methods described herein can be at least one of: solvent (e.g., acetone, isopropyl alcohol (IPA), or ultrasonic cleaning to remove organic contaminants and particles) or acid (e.g., sulfuric acid (H₂SO₄) or hydrochloric acid (HCl)), cleaning; plasma (e.g., using reactive gases like oxygen (O₂), hydrogen (H₂), or fluorine-based gases (CF₄, SF₆), is done to remove native oxide layers or to pattern the substrate surface), and/or wet (e.g., to remove unwanted layers or roughen the surface for improved film adhesion for example, for sequential infiltration synthesis etching; and surface functionalization (e.g., silane coupling agents, such as APTES (aminopropyltriethoxysilane) or HMDS (hexamethyldisilazane), by introducing specific chemical groups that enhance film bonding or modify surface energy).

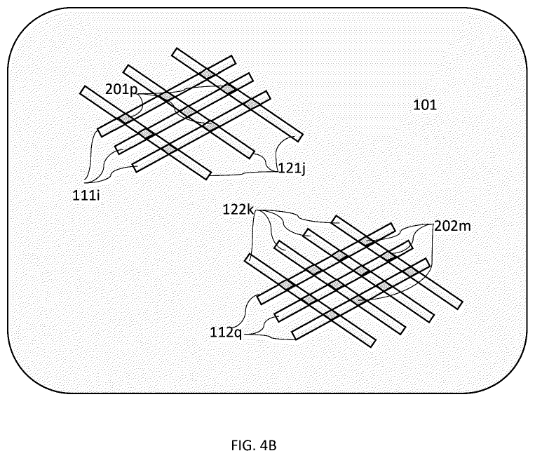

Accordingly and in an exemplary implementation (see e.g., FIG. 4A), provided herein is a method of forming an etching mask, or a portion thereof for lithography in a semiconductor production process, the etching mask having its smallest feature 201 at a substrate 100 plane, implemented in a microreactor direct atomic layer deposition (μDALP) system, the method comprising: using the μDALP system, depositing and/or removing a first strip 110; and using the μDALP system, depositing and/or removing a second strip 120, wherein: the first and second strips are configured to form a crossing pattern with a predetermined overlap region 200; the crossing pattern adapted, sized, and configured to form two acute angles θ₁, θ₂, with the smallest feature 201 defined at the acute angle θ₁, θ₂, formed by the first strip 110 and the second strip 120 forming at least the portion of the etching mask.

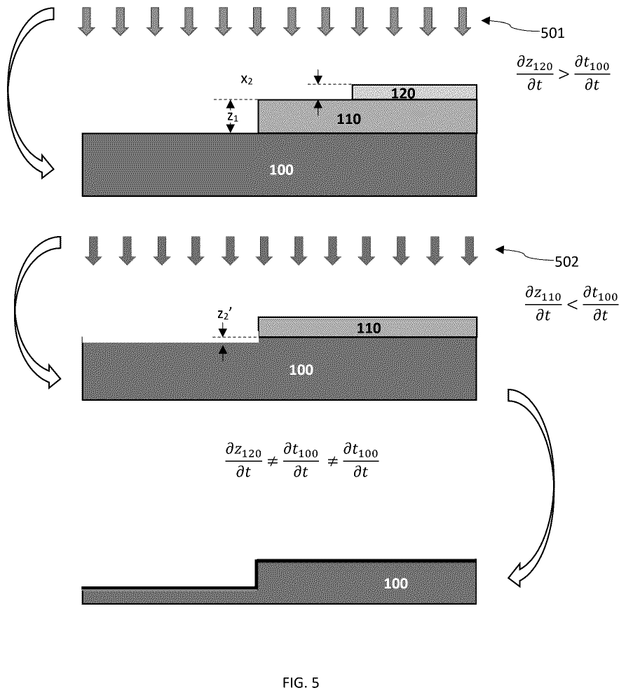

As illustrated in FIG. 5, the etching mask can be used for patterning the surface of the wafer, essentially transferring a mirror image of the mask formed (see e.g., FIGS. 2B, 4A, 4B) onto the wafer. As described, in an exemplary implementation, Trimethylaluminum (TMA) precursor is deposited on a silicon wafer 100 following surface treatment with dilute solution of hydrofluoric acid (HF) using the μDALP system, which can then be reacted with ozone (O₃), to form a strip 110 of aluminum oxide (Al₂O₃) having thickness of z₁ after repeating the process for a predetermined number of cycles. The second strip can be formed using the same or different μDALP nozzle, with Tetrakis (dimethylamino) titanium (TDMAT) as a precursor, and plasma O₂ as reactant to form a TiO2 strip 120 having thickness z₂ (see e.g., cross section, FIG. 5 top). Then, oxposing the wafer to a wet etchant, that can etch both the wafer and the TiO2 strip, each of the TiO2 strip 120, the Al2O3 strip 110 and the wafer 100 at a predetermined etching ratio (dz/dt), the whole thickness z₂ of the TiO2 strip 120 will be removed, as well as a fraction z₂′of the wafer. The etchant can be, for example a mixture of hydrofluoric acid (HF) and nitric acid (HNO₃), commonly known as piranha solution or buffered oxide etch (BOE), where the etching rate will depend on the fractional concentration of HF, temperature and other parameters. Then, following the elimination of the top layer, at a fixed, predetermined time, the wafer (see FIG. 5, middle), can be exposed to another etchant using the same μDALP with the same or another nozzle, to remove the thickness z₁ of strip 110, using for example reactive ion etching (RIE) with sulfur hexafluoride (SF₆), or carbon tetrafluoride (CF4) gasses with controlled flowrate configured to etch the silicon wafer 100 faster than the Al2O3 strip 110, the depth z₁′ of wafer etching can be controlled.

In other exemplary implementations, etching methodologies, etchants and strips can be used to transfer complex patterns into the wafer, such as making precise divots for ball grid arrays, integrated circuit legs' wells and the like.

Turning to FIG. 1, illustrating a typical process for formation of an etching mask as used in lithography. As illustrated, typically, the process of forming an etching mask film involves several sequential steps to create a pattern on a substrate that will serve as a protective mask for the subsequent etching process (in other words, as an etching mask). Initially, the substrate is prepared by cleaning 10 to eliminate contaminants, ensuring optimal adhesion for the mask film onto the substrate.

Surface treatment of the substrate used in the methods described herein can be at least one of: solvent (e.g., acetone, isopropyl alcohol (IPA), or ultrasonic cleaning to remove organic contaminants and particles) or acid (e.g., sulfuric acid (H₂SO₄) or hydrochloric acid (HCl)), cleaning; plasma (e.g., using reactive gases like oxygen (O₂), hydrogen (H₂), or fluorine-based gases (CF₄, SF₆), is done to remove native oxide layers or to pattern the substrate surface), and/or wet (e.g., to remove unwanted layers or roughen the surface for improved film adhesion; and surface functionalization (e.g., silane coupling agents, such as APTES (aminopropyltriethoxysilane) or HMDS (hexamethyldisilazane), by introducing specific chemical groups that enhance film bonding or modify surface energy).

Then, the selection of an appropriate mask film material follows 11, whether choosing a photosensitive or protective material or other materials, depending on the etching process(es) used. Subsequently, the chosen mask film material is applied 12 to the substrate through various deposition methods, including spin coating and dip coating, and undergoes a soft bake to remove excess solvents 13 and enhance adhesion. The next phase involves designing the mask pattern layout 14, which explicitly defines areas to be protected and those slated for etching. Precise alignment 15 of the mask with the substrate is done to guarantee the accurate positioning of the mask pattern. Then, in case of photolithography, the pattern can be exposed 16 to a light source, commonly ultraviolet (UV) light, ensues, utilizing the photomask to transfer the pattern onto the mask film. A bake step 17 can be a step prior to exposure (pre-bake) after exposure (post-bake/hardening) the exposed mask film.

In certain exemplary implementations, ultraviolet wavelength light sources used in the processes disclosed vary depending on the specific type of lithography. For traditional ultraviolet lithography, mercury lamps emitting at 365 nm (i-line) are used. Deep ultraviolet (DUV) lithography when used, employs excimer lasers, such as krypton fluoride (KrF) lasers with a wavelength of 248 nm and argon fluoride (ArF) lasers with a wavelength of 193 nm, to achieve higher resolution. Else, Extreme ultraviolet (EUV) lithography uses in certain exemplary implementations a significantly shorter wavelength of 13.5 nm, generated by laser-produced tin plasma sources.

Following this, the mask film is developed 18 with a chemical developer, removing either the exposed areas for positive photoresist or unexposed areas for negative photoresist, thereby revealing the pattern. An additional post-bake hardens 19 the mask pattern while eliminating residual solvents. Thorough inspection and quality control (not shown) are conducted to identify any defects, ensure uniformity, and validate pattern fidelity, with repairs or rework performed as necessary. The etching or patterning process is then executed 20, with the developed mask film acting as a protective layer for selected areas during etching. Optionally, the mask film may be removed after the etching process 21, with the removal method contingent on the type of mask material employed. Subsequently, the substrate is cleaned 22, and a final inspection is performed on the etched pattern to ensure adherence to specifications. Additional post-processing steps, such as deposition, implantation, or material modification, may be applied as needed. Ultimately, a final quality check is conducted to verify the precision and quality of the completed etched pattern.

As illustrated, using the methods disclosed herein steps 12-20, can be done using the (microreactor) DALP system disclosed. In an exemplary implementation, the crossing pattern is configured to form an alignment marking on the substrate for the etching mask, thereby also addressing step 15. The elimination of these steps can result in a significant cost-reduction and increased efficiency of the process.

In an exemplary implementation, as further illustrated in FIG. 4A, the step is one of depositing (rather than removing) the first strip, which comprises depositing a first material (e.g., platinum, silicon, titanium and the like) configured to form a film having predetermined thickness (see e.g., FIG. 2A h₁₁₀, about 20 nm), and the step of depositing the second strip comprises depositing a second material configured to form a film having predetermined thickness (see e.g., FIG. 2A h₁₂₀, about 24 nm) on the substrate 100. The second material can be, for example and as illustrated in FIG. 2A, illustrating the 2D ellipsometry image of titanium oxide (second material 120) on silicon (first material 110) stripes (or ribbon, or channel, or rail) on silicon oxide wafer (substrate 100), with FIG. 2B depicting ellipsometry image of surface profile measurement at the overlap 200 region. Likewise, FIG. 3 illustrates a close-up of overlap region 200 using platinum as the second strip, on a first silicon strip on silicon oxide 100 wafer.

The deposited materials can be resistant to the etching process, or in another example, sensitive to the etching process. For example, the first and/or second material can be Silicon Dioxide (SiO₂) used as an insulating material and demonstrates robust resistance to a variety of wet and dry etching techniques. Similarly, Silicon Nitride (Si₃N₄) can be used as etching resistance such as reactive ion etching (RIE) and wet chemical etching. Additionally, materials such as Tantalum Pentoxide (Ta₂O₅), Aluminum Oxide (Al₂O₃), Hafnium Oxide (HfO₂), Titanium Nitride (TIN), Platinum (Pt), and perfluorinated polymers can be used. Conversely, the first and/or second material can be sensitive to specific etching processes. For example, metals like Aluminum (Al) and Copper (Cu) can be deposited as etchable layers, and Zinc Oxide (ZnO) thin films are sensitive to certain etchants, particularly acids. These materials are configured to be removed selectively, facilitating the creation of intricate structures and features.

In an exemplary implementation, the lithography processes implementing the masks formed using the methods disclosed, can be, for example, photolithography, Extreme Ultraviolet Lithography (EUV), e-beam lithography, nanoimprint lithography, x-ray lithography, focused ion-beam lithography (FIB), scanning probe lithography, directed self-assembly (DSA) lithography, or a lithography process comprising one or more of the foregoing. For example, EUV lithography uses extremely short wavelengths of light in the extreme ultraviolet range. EUV enables the production of smaller features due to its shorter wavelength, enhancing resolution. In an exemplary implementation, using deposited acrylates using DALP as the first and/or second material, will enable forming the etching mask disclosed. Consequently, and depending on the lithography process used, the etching process is selected from the group consisting of: reactive ion etching (RIE), deep reactive ion etching (DRIE), ion beam etching (IBE), chemical vapor etching (CVE), wet chemical etching, plasma etching, laser ablation, electron beam etching, and photolithography-assisted etching.

For example, Chemical Vapor Etching (CVE) refers to a technique in which thin films are etched on a substrate through the chemical reaction of vapor-phase first surface modifiers. In CVE, the process begins with a substrate, (e.g., a wafer), in contact with the (microreactor) DALP chamber. The chamber is filled with the carrier gas to provide a controlled environment. The substrate is exposed to a pair of reactive gases or vapor-phase reactive chemicals within the chamber. These chemicals chemically react with the material on the substrate surface, leading to the removal or modification of that material. The process typically involves the adsorption of reactants onto the substrate surface, followed by chemical reactions that result in the formation of volatile by-products. These by-products are then removed from the system, leaving behind the desired etched or modified pattern. CVE can be selective, targeting specific materials while leaving others intact, and it can be used for both isotropic and anisotropic etching.

In an exemplary implementation, the precise parameters and reactants used in the CVE processes disclosed herein, vary depending on the materials and the specific etching requirements. The reactions occurring at the substrate surface can involve a range of processes such as thermal decomposition, pyrolysis, plasma-enhanced reactions, or a combination thereof.

Likewise, Reactive Ion Etching (RIE) refers to a highly precise and anisotropic dry etching process used in microfabrication and semiconductor manufacturing. RIE involves the removal of material from a substrate, e.g., a silicon wafer, using chemically reactive ions and a plasma. During RIE, the substrate is placed in a chamber under vacuum, where a low-pressure plasma is generated, usually consisting of reactive gases like fluorine or chlorine. This plasma is then ignited into a high-energy state by, for example, applying radiofrequency (RF) power. The reactive ions in the plasma are accelerated towards the substrate, where they chemically react with the material to be etched. The chemical selectivity of the process allows for precise control over the etching, while the anisotropic nature ensures that material is removed predominantly in the vertical direction, creating well-defined and high-aspect-ratio features.

In an exemplary implementation, the at least one material deposited and/or removed comprises a chemical vapor deposition (CVD) precursor or a plasma-enhanced atomic layer deposition (PEALD, referring to deposition processes only), precursor as described herein. In addition, another exemplary implementation, the first and/or second material in gas or plasma phase used for CVD, or PEALD can be one or a mixture of: HF, CHF₃, CF₄·, H₂, NF₃, XeF₂, BCl₃/Cl₂, C₄H₃F₇O, C₃H₃F₃, HBr, O₂, CF₄/O₂ F₂/He, C₄F₈, CH₃F, Al(CH₃)₃, C₄F₈ plasma, WF₆, BCl₃, SF₄, SO₂Cl₂, and Hacac. It is noted that the choice of materials depends on factors such as process requirements, film properties, equipment capabilities, and cost considerations. Additionally, specific applications or variations within (microreactor) DALP material removal techniques may call for the use of other reagents or reagent gas mixtures.

As further illustrated in FIG. 4B, the step of depositing and/or removing the first strip, and the step of depositing and/or removing the second film strip, configured to form a predetermined pattern of crossed film strips, each pattern comprised of a plurality of first strip material 111i, 112q, crossed by a plurality of second strip material 121j, 122k, forming a plurality of overlap regions 201p, 202m, defining a plurality of acute angles at the substrate 101 level. As illustrated, the number of first and second strips in each pattern does not necessarily has to be even, thereby providing a plurality of features at predetermined distances.

### Definitions

In an exemplary implementation, the term “etching mask” means any film layer or any solid mask used to protect one or more portion(s) of a layer or of several layers during an etching process. Moreover, the term “etching mask film” means both a film serving as a partial layer of optical functional film so that it is partially left in the photomask form and a film serving as a process assisting film during etching of the underlying film adjacent to the transparent substrate so that its entirety is finally removed.

In the context of the disclosure, the term “feature” refers to an individual element or component of a pattern that is being transferred onto the substrate. These features can include various shapes, such as lines, spaces, dots, or any other geometric structures, and they collectively form the overall pattern that defines the layout or design on the substrate. Features are typically characterized by their critical dimensions, which may include their width, spacing, and shape.

In the context of the disclosure, the term “substrate” refers to the foundational material or base upon which semiconductor devices are fabricated. It provides mechanical support and serves as the platform for the deposition of various layers, such as semiconducting, insulating, and conducting materials, which are essential for forming integrated circuits. Substrates are typically made of materials like silicon, gallium arsenide, or sapphire, chosen based on their electrical, thermal, and structural properties. The substrate's crystalline structure and surface quality are used in determining the performance and reliability of the semiconductor device.

In the context of the disclosure, the term “plasma-enhanced atomic layer deposition,” or PEALD, refers to a variation of atomic layer deposition (ALD) that incorporates plasma to enhance the chemical reactions during the deposition process. PEALD uses a plasma source to generate highly reactive species, such as radicals and ions, which enable film growth at lower temperatures compared to traditional thermal ALD. This makes PEALD particularly suitable for depositing thin films on thermally sensitive substrates or achieving materials with specific properties that are challenging to produce using thermal methods.

In the context of the disclosure, while the term “photoresist” refers to a photosensitive resin, the solubility of which varies in a developing solution due to the action of light, to thus obtain an image corresponding to the exposure pattern; the term “positive photoresist” refers to a light-sensitive material used in photolithography where the exposed areas become more soluble in a developer solution after exposure to ultraviolet (UV) light. The chemical structure of the resist changes upon exposure, allowing the developer to selectively remove the exposed regions, leaving behind an identical copy of the mask pattern on the substrate. Conversely, the term “negative photoresist”, in the context of the disclosure, refers to a light-sensitive material in which exposure to UV light causes polymerization or crosslinking, making the exposed areas insoluble in the developer solution. The unexposed regions are dissolved during development, leaving behind an inverse pattern of the mask on the substrate. Negative photoresists can be advantageous in applications requiring thicker films, better adhesion, and lower processing costs, though they typically offering lower resolution compared to positive resists.

The terms “first,” “second,” and the like, when used herein do not denote any order, quantity, or importance, but rather are used to denote one element from another. The terms “a”, “an” and “the” herein do not denote a limitation of quantity and are to be construed to cover both the singular and the plural, unless otherwise indicated herein or clearly contradicted by context. The suffix “(s)” as used herein is intended to include both the singular and the plural of the term that it modifies, thereby including one or more of that term (e.g., the film(s) includes one or more film).

Reference throughout the specification to “one exemplary implementation”, “another exemplary implementation”, “an exemplary implementation”, and so forth, means that a particular element (e.g., feature, structure, and/or characteristic) described in connection with the exemplary implementation is included in at least one exemplary implementation described herein, and may or may not be present in other exemplary implementations. In addition, it is to be understood that the described elements may be combined in any suitable manner in the various exemplary implementations.

In addition, for the purposes of the present disclosure, directional or positional terms such as “top”, “apical”, “basal”, “proximal”, “distal”, “bottom”, “upper,” “lower,” “side,” “front,” “frontal,” “forward,” “rear,” “rearward,” “back,” “trailing,” “above,” “below,” “left,” “right,” “radial,” “vertical,” “upward,” “downward,” “outer,” “inner,” “exterior,” “interior,” “intermediate,” etc., are merely used for convenience in describing the various exemplary implementations of the present disclosure.

The term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms, “including”, “having” and their derivatives.

In the context of the disclosure, the term “operable” means the system and/or device and/or program, or a certain element or step being operable, is fully functional, sized, adapted and calibrated, comprises elements for, and meets applicable operability requirements to perform a recited function when activated, coupled, implemented, actuated, effected, realized, or when an executable program is executed by at least one processor associated with the system and/or the device. In relation to systems and circuits, the term “operable” means the system and/or the circuit is fully functional and calibrated, comprises logic for, having the hardware and firmware necessary, as well as the circuitry for, and meets applicable operability requirements to perform a recited function when executed by at least one processor.

Accordingly, provided herein is a method of forming an etching mask, or a portion thereof for lithography in a semiconductor production process, the etching mask having its smallest feature at a substrate plane, implemented in a microreactor direct atomic layer deposition (μDALP) system, the method comprising: using the μDALP system, depositing and/or removing a first strip; and using the μDALP system, respectively depositing and/or removing a second strip (in other words, if the first strip was added, the second strip is added; and if the first strip is removed, the second strip is removed), wherein: the first and second strips are configured to form a crossing pattern with a predetermined overlap region; and the crossing pattern adapted, sized, and configured to form two acute angles with the smallest feature defined at the acute angle formed by the first strip and the second strip forming at least the portion of the etching mask, wherein (i) the step of depositing the first strip-comprises depositing a first material strip configured to form a film having predetermined thickness; and the step of depositing the second strip comprises depositing a second material configured to form a film having predetermined thickness; and conversely, (ii) the step of removing the first strip-comprises removing a first material strip film having predetermined thickness; and the step of removing the second strip comprises removing a second material strip having predetermined thickness, (iii) the first and/or second material forming the first strip and/or the second strip respectively is resistant to an etching process, or (iv) the first and/or second material forming the first strip and/or the second strip respectively is sensitive to an etching process, wherein (v) the (e.g., additive) lithography is selected from the group consisting of: photolithography, Extreme Ultraviolet Lithography (EUV), e-beam lithography, nanoimprint lithography, x-ray lithography, focused ion-beam lithography (FIB), scanning probe lithography, directed self-assembly (DSA) lithography, or a lithography process comprising one or more of the foregoing, wherein (vi) the etching process is selected from the group consisting of: reactive ion etching (RIE), deep reactive ion etching (DRIE), ion beam etching (IBE), chemical vapor etching (CVE), wet chemical etching, plasma etching, laser ablation, electron beam etching, and photolithography-assisted etching, wherein (vii) the first strip is deposited and/or removed in parallel with the substrate plane, the method further comprising (viii) exposing the substrate to an ultraviolet (UV) light source at a wavelength operable to develop the etching mask after depositing and/or removing the material, wherein (ix) the at least one material deposited or removed in the first strip and second strip comprises a photosensitive material, (x) the at least one material deposited and/or removed comprises a chemical vapor deposition (CVD) precursor or a plasma-enhanced atomic layer deposition (PEALD) precursor, the method further comprising (xi) using the μDALP system to deposit an antireflective coating (ARC) layer on the substrate prior to depositing and/or removing the material, wherein (xii) the step of depositing and/or removing the first strip, and the step of respectively depositing and/or removing the second film strip, configured to form a predetermined pattern of crossed film strips, each pattern comprised of a plurality of first strip material, crossed by a plurality of second strip material, the method further comprising (xiii) exposing the substrate to a photoresist before depositing and/or removing the material, and using the photoresist as a patterned mask for depositing and/or removing the material corresponding to the first or second strip, wherein (xiv) the crossing pattern is configured to form an alignment marking on the substrate for the etching mask, the method further comprising (xv), using a first etchant (referring to chemicals used to dissolve layers of targeted material), removing the second strip and a first portion of the substrate at a predetermined first rate ratio (change in thickness/time e.g., dz/dt); and using a second etchant, removing the second strip and a second portion of the substrate at a predetermined second rate ratio, wherein (xvi) the etching rate of the first strip is faster than the etching rate of the substrate, (xvii) slower (xviii) or the same as the etching rate of the substrate, wherein (xix) etching rate of the second strip is faster than, (xx) slower than, or (xxi) the same as the etching rate of the substrate, wherein (xxii) the step of removing the second strip and the first portion of the substrate, and the step of removing the first strip and the second portion of the substrate are performed using the same etching process, or wherein (xxiii) the step of removing the second strip and the first portion of the substrate, and the step of removing the first strip and the second portion of the substrate are performed using a different etching process.

While in the foregoing specification the devices, systems and methods of forming etch masks having fine features at the substrate level, using direct atomic layer processing (DALP), have been described in relation to certain preferred exemplary implementations, and many details are set forth for purpose of illustration, it will be apparent to those skilled in the art that the disclosure is susceptible to additional exemplary implementations and that certain of the details described in this specification and as are more fully delineated in the following claims can be varied considerably without departing from the basic principles of this disclosure.

1. A method of forming an etching mask, or a portion thereof for lithography in a semiconductor production process, the etching mask having its smallest feature at a substrate plane, implemented in a microreactor direct atomic layer deposition (μDALP) system, the method comprising:
a. using the μDALP system, depositing and/or removing a first strip; and
b. using the μDALP system, respectively depositing and/or removing a second strip, wherein:
the first and second strips are configured to form a crossing pattern with a predetermined overlap region; and the crossing pattern adapted, sized, and configured to form two acute angles with the smallest feature defined at the acute angle formed by the first strip and the second strip forming at least the portion of the etching mask.

2. The method of claim 1, wherein:
a. the step of depositing the first strip comprises depositing a first material configured to form a film having predetermined thickness; and
b. the step of depositing the second strip comprises depositing a second material configured to form a film having predetermined thickness.

3. The method of claim 2, wherein the first and/or second material forming the first strip and/or the second strip respectively is resistant to an etching process.

4. The method of claim 2, wherein the first and/or second material forming the first strip and/or the second strip respectively is sensitive to an etching process.

5. The method of claim 1, wherein the lithography is selected from the group consisting of: photolithography, Extreme Ultraviolet Lithography (EUV), e-beam lithography, nanoimprint lithography, x-ray lithography, focused ion-beam lithography (FIB), scanning probe lithography, directed self-assembly (DSA) lithography, or a lithography process comprising one or more of the foregoing.

6. The method of claim 5, wherein the etching process is selected from the group consisting of: reactive ion etching (RIE), deep reactive ion etching (DRIE), ion beam etching (IBE), chemical vapor etching (CVE), wet chemical etching, plasma etching, laser ablation, electron beam etching, and photolithography-assisted etching.

7. The method of claim 1, wherein the first strip is deposited and/or removed in parallel with the substrate plane.

8. The method of claim 1, further comprising exposing the substrate to an ultraviolet (UV) light source at a wavelength operable to develop the etching mask after depositing and/or removing the material.

9. The method of claim 1, wherein the at least one material deposited or removed in the first strip and second strip comprises a photosensitive material.

10. The method of claim 1, wherein the at least one material deposited and/or removed comprises a chemical vapor deposition (CVD) precursor or a plasma-enhanced atomic layer deposition (PEALD) precursor.

11. The method of claim 1, further comprising using the μDALP system to deposit an antireflective coating (ARC) layer on the substrate prior to depositing and/or removing the material.

12. The method of claim 1, wherein the step of depositing and/or removing the first strip, and the step of respectively depositing and/or removing the second film strip, configured to form a predetermined pattern of crossed film strips, each pattern comprised of a plurality of first strip material, crossed by a plurality of second strip material.

13. The method of claim 1, further comprising exposing the substrate to a photoresist before depositing and/or removing the material, and using the photoresist as a patterned mask for depositing and/or removing the material.

14. The method of claim 1, wherein the crossing pattern is configured to form an alignment marking on the substrate for the etching mask.

15. The method of claim 2, further comprising:
a) using a first etchant, removing the second strip and a first portion of the substrate at a predetermined first rate ratio; and
b) using a second etchant, removing the second strip and a second portion of the substrate at a predetermined second rate ratio.

16. The method of claim 15, wherein the etching rate of the first strip is faster than the etching rate of the substrate.

17. The method of claim 15, wherein the etching rate of the first strip is slower than the etching rate of the substrate.

18. The method of claim 15, wherein the etching rate of the first strip is the same as the etching rate of the substrate.

19. The method of claim 15, wherein the etching rate of the second strip is faster than the etching rate of the substrate.

20. The method of claim 15, wherein the etching rate of the second strip is slower than the etching rate of the substrate.

21. The method of claim 15, wherein the etching rate of the second strip is same as the etching rate of the substrate.

22. The method of claim 15, wherein the step of removing the second strip and the first portion of the substrate, and the step of removing the first strip and the second portion of the substrate are performed using the same etching process.

23. The method of claim 15, wherein the step of removing the second strip and the first portion of the substrate, and the step of removing the first strip and the second portion of the substrate are performed using a different etching process.
